(19) United States
(12) Patent Application Publication
(10) Pub. No.: US 2020/0266216 A1
(43) Pub. Date: Aug. 20, 2020

(54) DISPLAY APPARATUS AND METHOD OF MANUFACTURING THE SAME

(71) Applicant: Samsung Display Co., Ltd., Yongin-si (KR)

(72) Inventors: Wangwoo LEE, Osan-si (KR); Moosoon KO, Seoul (KR); Minwoo WOO, Seoul (KR)

(21) Appl. No.: 16/787,985

(22) Filed: Feb. 11, 2020

(30) Foreign Application Priority Data
Feb. 20, 2019 (KR) 10-2019-0019943

(51) Int. Cl. H01L 27/12

(52) U.S. Cl. CPC H01L 27/124; H01L 21/02063; H01L 2227/323; H01L 27/1259

(57) ABSTRACT

A display apparatus includes a base substrate, an active layer on the base substrate and including a first active pattern, a first insulating layer on the active layer, a first gate conductive layer on the first insulating layer, a second insulating layer on the first gate conductive layer, and a third gate conductive layer on the second insulating layer, and including a third-a gate pattern. The third gate conductive layer is not directly connected to the first gate conductive layer.

### CROSS-REFERENCE TO RELATED APPLICATION

This application claims priority to and the benefit of Korean Patent Application No. 10-2019-0019943, filed on Feb. 20, 2019, the entire disclosure of which is herein incorporated by reference.

### BACKGROUND

### 1. Field

Example embodiments of the inventive concept relate to a display apparatus and a method of manufacturing the display apparatus. More particularly, example embodiments of the inventive concept relate to a display apparatus and a method of manufacturing the display apparatus capable of improving display quality.

### 2. Description of the Related Art

Recently, display apparatuses having light weights and small sizes have been manufactured. Cathode ray tube (CRT) display apparatuses has been used in the past due to performance and competitive prices. However, CRT display apparatuses have limitations due to their large size and/or poor portability. Therefore display apparatuses such as , liquid crystal display apparatuses and an organic light emitting display apparatuses have been highly regarded due to their small size, light weight and low-power-consumption.

Display apparatuses may include a gate conductive layer constituting a scan line or the like. As the display apparatus is enlarged and resolution is increased, high-speed driving is desirable. However, the scan signal transmitted through the gate conductive layer can be delayed due to the enlarged display apparatus, and the display quality may be degraded. Accordingly, it is necessary to lower the resistance value of the gate conductive layer without creating manufacturing process problems.

### SUMMARY

One or more example embodiments of the inventive concept provide a display apparatus including a low-resistance gate conductive layer with improved display quality.

One or more example embodiments of the inventive concept also provide a method of manufacturing the display apparatus.

According to an example embodiment of the inventive concept, a display apparatus includes a base substrate, an active layer on the base substrate and including a first active pattern, a first insulating layer on the active layer, a first gate conductive layer on the first insulating layer, a second insulating layer on the first gate conductive layer, and a third gate conductive layer on the second insulating layer, and including a third-a gate pattern. The third gate conductive layer is not directly connected to the first gate conductive layer.

In an example embodiment, the third-a gate pattern may be directly connected to the first active pattern through a first contact hole formed through the second insulating layer and the first insulating layer.

In an example embodiment, the display apparatus may further include a fourth insulating layer on the third gate conductive layer, and a source drain conductive layer on the fourth insulating layer, and including a first SD pattern and a second SD pattern.

The first gate conductive layer may include a first-a gate pattern and a first-b gate pattern. The first-a gate pattern may overlap the first active pattern, and the first-b gate pattern may be spaced apart from the first-a gate pattern. The first SD pattern may be directly connected to the third-a gate pattern through a second contact hole formed through the fourth insulating layer. The second SD pattern may be directly connected to the first-b gate pattern through a third contact hole formed through the fourth insulating layer and the second insulating layer.

In an example embodiment, the display apparatus may further include a second gate conductive layer on the second insulating layer, and a third insulating layer on the second gate conductive layer under the third gate conductive layer. The third gate conductive layer might not be directly connected to the second gate conductive layer.

In an example embodiment, the third-a gate pattern may be directly connected to the first active pattern through a first contact hole formed through the second insulating layer and the first insulating layer.

In an example embodiment, the active layer may include poly silicon.

In an example embodiment, the first gate conductive layer may be formed of a single layer of aluminum or an aluminum alloy.

In an example embodiment, the first gate conductive layer may include a main conductive layer and a capping layer on the main conductive layer.

In an example embodiment, the main conductive layer may be formed of a single layer of aluminum or an aluminum alloy, and the capping layer may include titanium (Ti) and may have a thickness of 100 Å (angstroms) or less.

In an example embodiment, the display apparatus may further include a sealing member between a display area in which an image is displayed and a peripheral area surrounding the display area, and a sealing substrate configured to seal elements in the display area with the sealing member. The first gate conductive layer may further include a first connecting line overlapping the sealing member. The third gate conductive layer may further include a shielding electrode between the first connecting line and the sealing member.

According to an example embodiment of the inventive concept, a display apparatus includes a base substrate including a display area in which an image is displayed and a peripheral area which is a non-display area adjacent to the display area, an active layer on the base substrate, a first insulating layer on the active layer, a first gate conductive layer on the first insulating layer, and including a first connecting line, a second insulating layer on the first gate conductive layer, a third gate conductive layer on the second insulating layer, and including a first shielding electrode overlapping the first connecting line, a fourth insulating layer on the third gate conductive layer, a sealing member on the fourth insulating layer between the display area and the peripheral area, and overlapping the first shielding electrode, and a sealing substrate configured to seal elements in the display area with the sealing member.

According to an example embodiment of the inventive concept, a method of manufacturing a display apparatus includes forming an active layer including a first active pattern on a base substrate, forming a first insulating layer on the active layer, forming a first gate conductive layer on the first insulating layer, forming a second insulating layer on the first gate conductive layer, forming a first contact hole exposing the first active pattern through the second insulating layer and the first insulating layer, and forming a third gate conductive layer including a third-a gate pattern directly connected to the first active pattern via the first contact hole on the second insulating layer. When forming the first contact hole, the first gate conductive layer is fully covered by the second insulating layer.

In an example embodiment, after the first contact hole is formed and before the third gate conductive layer is formed, the method may further include cleaning a surface of the first active pattern which is exposed by the first contact hole with a cleaning solution for etching metal.

In an example embodiment, in cleaning the surface of the first active pattern, a wet cleaning process using a BOE (Buffered Oxide Etchant) may be performed.

In an example embodiment, after the first gate conductive layer is formed and before the second insulating layer is formed, the method may further include forming a source region and a drain region by doping impurities in a portion of the active layer, and activating the active layer by heat treating the active layer in order to activate the dopant.

In an example embodiment, the first gate conductive layer may include a connecting line. The third gate conductive layer may include a shielding electrode overlapping the connecting line.

In an example embodiment, the method may further include forming a sealing member on a sealing substrate, bonding the sealing substrate and the base substrate on which the third gate conductive layer is formed using the sealing member, and hardening the sealing member by irradiating the sealing member through the sealing substrate with a laser. The shielding electrode may be between the sealing member and the connecting line in order to block the connecting line from being irradiated by the laser.

In an example embodiment, before forming the third gate conductive layer, the method may include forming a second gate conductive layer on the second insulating layer, and forming a third insulating layer on the second gate conductive layer.

In an example embodiment, the first gate conductive layer may be formed of a single layer of aluminum or an aluminum alloy.

In an example embodiment, the third gate conductive layer may include molybdenum or molybdenum alloys.

According to the example embodiments of the present inventive concept, the display apparatus includes a base substrate, an active layer on the base substrate and including a first active pattern, a first insulating layer on the active layer, a first gate conductive layer on the first insulating layer, a second insulating layer on the first gate conductive layer, and a third gate conductive layer including an third-a gate pattern on the second insulating layer. The third gate conductive layer may not be directly connected to the first gate conductive layer or the second gate conductive layer through a contact hole. Therefore, since the first gate conductive layer and the second gate conductive layer are entirely covered by the second insulating layer and the third insulating layer, in a cleaning process using a cleaning solution, the first and second gate conductive layers do not require an additional capping layer, or they may require only a very thin capping layer. Accordingly, manufacturing process problems can be decreased or solved while reducing wiring resistance, and the display apparatus can be realized with a simple structure that reduces manufacturing cost.

In addition, the sealing member is irradiated with a laser through a sealing substrate. At this time, a shielding electrode may prevent or substantially prevent the laser beam from irradiating a connecting line. Accordingly, it is possible to prevent or reduce damage to the connecting line, which may include aluminum, due to laser irradiation.

It is to be understood that both the foregoing general description and the following detailed description are example and explanatory and are intended to provide further explanation of the invention as claimed.

### BRIEF DESCRIPTION OF THE DRAWINGS

The above and other features of the inventive concept will become more apparent by describing in detail example embodiments thereof with reference to the accompanying drawings, in which:

FIG. 1 is a cross-sectional view of a display apparatus according to an example embodiment of the inventive concept;

FIG. 2 is a plan view of a display apparatus according to an example embodiment of the inventive concept;

FIG. 3 shows cross-sectional views taken along the line I-I′ and the line II-II′ of FIG. 2;

FIG. 4 is a partially enlarged cross-sectional view of a display apparatus according to an example embodiment of the inventive concept;

FIGS. 5A-5F are cross-sectional views illustrating a method of manufacturing the display apparatus of FIG. 3;

FIG. 6 is a block diagram of an electronic device according to example embodiments;

FIG. 7A is a diagram of an example embodiment in which the electronic device of FIG. 6 is implemented as a television; and

FIG. 7B is a diagram of an example embodiment in which the electronic device of FIG. 6 is implemented as a smart phone.

### DETAILED DESCRIPTION

Hereinafter, the inventive concept will be explained in detail with reference to the accompanying drawings. The present invention, however, may be embodied in various different forms, and should not be construed as being limited to only the example embodiments herein. Rather, these embodiments are provided as examples so that this disclosure will be thorough and complete, and will fully convey the aspects and features of the present invention to those skilled in the art. Accordingly, processes, elements, and techniques that are not necessary to those having ordinary skill in the art for a complete understanding of the aspects and features of the present invention may not be described. Unless otherwise noted, like reference numerals denote like elements throughout the attached drawings and the written description, and thus, descriptions thereof will not be repeated. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments only and is not intended to be limiting of the present invention. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

The electronic or electric devices and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the exemplary embodiments of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

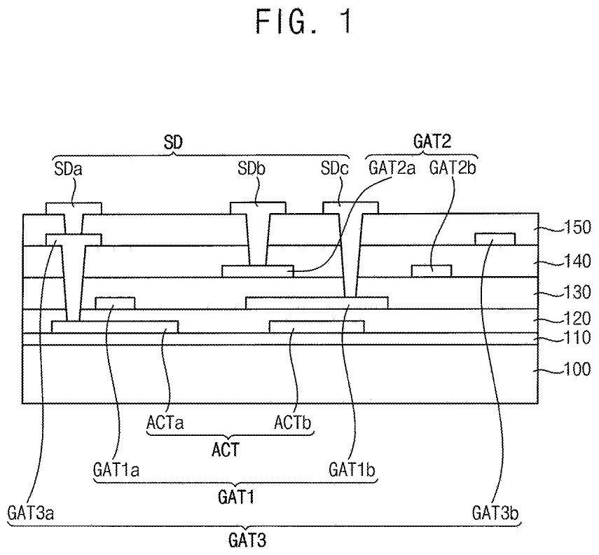

FIG. 1 is a cross-sectional view illustrating a display apparatus according to an example embodiment of the inventive concept.

Referring to FIG. 1, the display apparatus may include a base substrate 100, a buffer layer 110, an active layer ACT, a first insulating layer 120, a first gate conductive layer GAT1, a second insulating layer 130, a second gate conductive layer GAT2, a third insulating layer 140, a third gate conductive layer GAT3, a fourth insulating layer 150 and a source drain conductive layer SD.

The base substrate 100 may include transparent or opaque insulation materials. For example, the base substrate 100 may include a quartz substrate, a synthetic quartz substrate, a calcium fluoride substrate, a fluoride-doped quartz substrate, a sodalime glass substrate, a non-alkali glass substrate etc. Alternatively, the base substrate 100 may include a flexible transparent material such as a flexible transparent resin substrate (e.g., a polyimide substrate). In this case, the polyimide substrate may include a first polyimide layer, a barrier film layer, a second polyimide layer, and/or other suitable layers that are known to a person of ordinary skill in the art.

The buffer layer 110 may be on the entire base substrate 100. The buffer layer 110 may prevent or reduce the diffusion of metal atoms and/or impurities from the base substrate 100 into the active layer. In addition, the buffer layer 110 may control a rate of a heat transfer during a crystallization process for forming the active layer ACT, thereby helping to obtain or obtaining a substantially uniform active layer ACT. In addition, the buffer layer 110 may improve the flatness of a surface of the base substrate 100 when the surface of the base substrate 100 is not uniform.

The active layer ACT may be on the buffer layer 110. The active layer ACT may include a first active pattern ACTa and a second active pattern ACTb. The active layer ACT may include a polysilicon (polycrystalline silicon). Each of the first and second active patterns ACTa, ACTb may include drain and source regions doped with an impurity and a channel region between the drain region and the source region. The polycrystalline silicon may be formed by first depositing amorphous silicon and then crystallizing the amorphous silicon. Here, the amorphous silicon may be crystallized by rapid thermal annealing (RTA), solid phase crystallization (SPC), excimer laser annealing (ELA), metal induced crystallization (MIC), metal induced lateral crystallization (MILC), sequential lateral solidification(SLS) and any other suitable methods. An impurity may be doped in portions of the active pattern ACT to form the source region and the drain region.

The first insulating layer 120 may cover the active layer ACT on the buffer layer 110, and may sufficiently cover the active layer ACT on the buffer layer 110, and may have a substantially flat upper surface without a step around the active layer ACT. Alternatively, the first insulating layer 120 may have a substantially uniform thickness along a profile of the active layer ACT. The first insulating layer 120 may include an inorganic insulating material such as a silicon compound or a metal oxide.

The first gate conductive layer GAT1 may be on the first insulating layer 120. The first gate conductive layer GAT1 may include a first-a gate pattern GAT1a and a first-b gate pattern GAT1b spaced apart from the first-a gate pattern GAT1a. The first-a gate pattern GAT1a may overlap the first active pattern ACTa and may be a gate electrode of a first thin film transistor. The first-b gate pattern GAT1b may overlap the second active pattern ACTb to form a gate electrode of the second thin film transistor. The first gate conductive layer GAT1 may further include a signal line such as a scan line for transmitting a scan signal. The first thin film transistor may be a switching element of a pixel, and the second thin film transistor may be a driving element of the pixel.

The first gate conductive layer GAT1 may be formed using a metal, an alloy, a metal nitride, a conductive metal oxide, a transparent conductive material, or other suitable material(s). For example, the first gate conductive layer GAT1 may be a single layer comprising aluminum (Al) or an aluminum alloy with low resistance and high conductivity. Thus, a wiring resistance can be reduced.

The second insulating layer 130 may be on the first insulating layer 120 on which the first gate conductive layer GAT1 is located. The second insulating layer 130 may sufficiently cover the first gate conductive layer GAT1 on the first insulating layer 120 and may have a substantially flat upper surface without forming a step around the first gate conductive layer. Alternatively, the second insulating layer 130 may cover the first gate conductive layer GAT1 on the first insulating layer 120, and may have substantially the same thickness along the profile of the first gate conductive layer. The second insulating layer 130 may include an inorganic insulating material such as a silicon compound or a metal oxide.

The second gate conductive layer GAT2 may be on the second insulating layer 130. The second gate conductive layer GAT2 may include a second-a gate pattern GAT2a and a second-b gate pattern GAT2b spaced apart from the second-a gate pattern GAT2a. The second gate conductive layer GAT2 may further include a signal line such as a scan line for transmitting a scan signal.

The second gate conductive layer GAT2 may be formed using a metal, an alloy, a metal nitride, a conductive metal oxide, a transparent conductive material, or other suitable material. For example, the second gate conductive layer GAT2 may be a single layer comprising aluminum (Al) or an aluminum alloy with low resistance and high conductivity. Thus, a wiring resistance can be reduced.

The third insulating layer 140 may be on the second insulating layer 130 on which the second gate conductive layer GAT2 is located. The third insulating layer 140 may sufficiently cover the second gate conductive layer GAT2 on the second insulating layer 130 and may have a substantially flat upper surface without forming a step around the second gate conductive layer GAT2. Alternatively, the third insulating layer 140 may cover the second gate conductive layer GAT2 on the second insulating layer 130, and may have substantially the same thickness along the profile of the second gate conductive layer GAT2. The third insulating layer 140 may include an inorganic insulating material such as a silicon compound or a metal oxide.

The third gate conductive layer GAT3 may be on the third insulating layer 140. The third gate conductive layer GAT3 may include a third-a gate pattern GAT3a and a third-b gate pattern GAT3b spaced apart from the third-a gate pattern GAT3a.

The third gate conductive layer GAT3 may be formed using a metal, an alloy, a metal nitride, a conductive metal oxide, a transparent conductive material, or other suitable material. For example, the third gate conductive layer GAT3 may be a single layer comprising molybdenum (Mo) or a molybdenum alloy. According to another embodiment, the third gate conductive layer GAT3 may include a laminated structure including a main conductive layer including molybdenum (Mo) or molybdenum alloy and a capping layer including titanium (Ti) on the main conductive layer.

The third gate conductive layer GAT3 may be directly connected to the active layer ACT through a contact hole formed through the third, second and first insulating layers 140, 130, and 120. However, the third gate conductive layer GAT3 is not directly connected to the first gate conductive layer GAT1 or the second gate conductive layer GAT2 through a contact hole.

For example, the third-a gate pattern GAT3a is directly connected to the first active pattern ACTa through a first contact hole formed through the third, second and first insulating layers 140, 130, and 120.

The fourth insulating layer 150 may be on the third insulating layer 140 on which the third gate conductive layer GAT3 is located. The fourth insulating layer 150 may sufficiently cover the third gate conductive layer GAT3 on the fourth insulating layer 150 and may have a substantially flat upper surface without forming a step around the third gate conductive layer GAT3. Alternatively, the fourth insulating layer 150 may cover the third gate conductive layer GAT3 on the third insulating layer 140, and may have substantially the same thickness along the profile of the third gate conductive layer GAT3. The fourth insulating layer 150 may include an inorganic insulating material such as a silicon compound or a metal oxide.

The source drain conductive layer SD may be on the fourth insulating layer 150. The source drain conductive layer SD may include a first SD pattern SDa, a second SD pattern SDb, and a third SD pattern SDc.

The source drain conductive layer SD may be directly connected to the third gate conductive layer GAT3, the second gate conductive layer GAT2, or the first gate conductive layer GAT1 through a contact hole. For example, the first SD pattern SDa may be directly connected to the third-a gate pattern GAT3a through a second contact hole formed through the fourth insulating layer 150. The second SD pattern SDb may be directly connected to the second-a gate pattern GAT2a through a third contact hole formed through the fourth insulating layer 150 and the third insulating layer 140. The third SD pattern SDc may be directly connected to the first-b pattern GAT1b through a fourth contact hole formed through the fourth insulating layer 150, the third insulating layer 140 and the second insulating layer 130.

The source drain conductive layer SD may be formed using a metal, an alloy, a metal nitride, a conductive metal oxide, a transparent conductive material, or other suitable material. The source drain conductive layer SD may be formed of a plurality of layers. For example, the source drain conductive layer SD may include a titanium (Ti) layer and a molybdenum (Mo) layer on the titanium layer (Ti/Mo structure). Alternatively, the source drain conductive layer SD may include a titanium (Ti) layer, an aluminum (Al) layer on the titanium layer, and a titanium (Ti) layer on the aluminum layer. (Ti/Al/Ti structure).

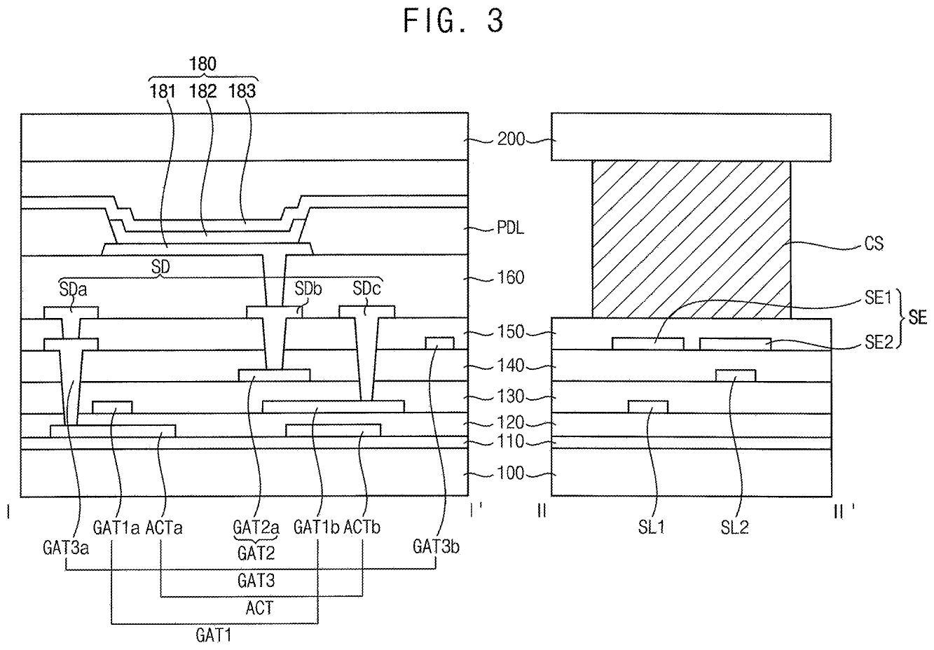

The display apparatus may further include a light emitting structure 180 or other suitable structure on the source drain conductive layer SD, as shown, for example, in FIG. 3.

As the display apparatus becomes larger, a resolution increases and a desire for high-speed driving increases. Accordingly, it is desirable to reduce the wiring resistance of the first or second gate conductive layer GAT1, GAT2. When the first or second gate conductive layer GAT1, GAT2 is formed of a conductive layer containing molybdenum, there is a limit to increasing the thickness of the conductive layer in order to reduce wiring resistance.

On the other hand, even if the first or second gate conductive layer GAT1, GAT2 has a low resistance, an excellent conductivity, and is made of a process-friendly metal, possibility of fault occurrence is still present during a heat treatment for the first or second gate conductive layer GAT1, GAT2, or during use of a BOE (Buffered Oxide Etchant) cleaning solution or other suitable solutions. Thus, a thick additional capping layer with a few thousand Å (Angstroms) of width is used on the conductive layer. In such cases, the wiring design is disadvantaged by the increased thickness, and it is difficult to finely process the pattern.

Accordingly, the additional capping layer with a thickness of several thousand Å (Angstroms) is used on the conductive layer. In such cases, a wiring design is disadvantaged by the increased thickness, and it is difficult to perform a fine pattern process.

On the other hand, according to the present embodiment, the third gate conductive layer GAT3 is not directly connected to the first gate conductive layer GAT1 or the second gate conductive layer GAT2 through a contact hole. Accordingly, because the first gate conductive layer GAT1 and the second gate conductive layer GAT2 are entirely covered by the second insulating layer 130 and the third insulating layer 140, respectively, during a cleaning process using the BOE solution, the first and second gate conductive layers GAT1, GAT2 do not require an additional capping layer, or a very thin capping layer is sufficient. Accordingly, problems with the manufacturing process can be decreased or solved while reducing the wire resistance, and the display apparatus can be realized with a simple structure that reduces manufacturing cost.

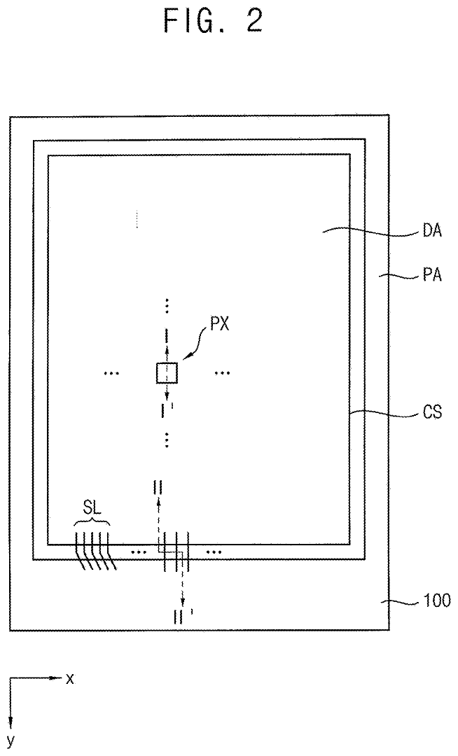

FIG. 2 is a plan view of a display apparatus according to an example embodiment of the inventive concept. FIG. 3 shows cross-sectional views taken along the line I-I′ and the line II-II′ of FIG. 2.

Referring to FIGS. 2 and 3, the display apparatus may include a display area DA in which an image is displayed, and a peripheral area PA which is a non-displaying area and surrounds the display area DA.

The display apparatus may include a plurality of pixels PX arranged in a matrix in the display area DA.

The display apparatus may include driving circuits in the peripheral area PA to generate driving signals for driving the plurality of pixels PX and connecting lines SL for transferring the driving signals into the display area DA. For example, the connecting lines SL may include a first connecting line SL1 and a second connecting line SL2.

A sealing member CS may be between the display area DA and the peripheral area PA. The sealing member CS may be between a sealing substrate 200 and a base substrate 100 to seal the display area DA where a light emitting structure 180 is formed (as shown in FIG. 3). The sealing member CS may be composed of a material which is melted by applying a thermal energy (e.g., a predetermined thermal energy). The sealing member CS may include a material which is cured by light. For example, the sealing member CS may include a glass frit.

Here, the connection wiring lines SL may be formed to pass through a boundary between the display area DA and the peripheral area PA, and overlap the sealing member CS.

Referring to FIG. 3, the display apparatus may include the base substrate 100, a buffer layer 110, an active layer ACT, a first insulating layer 120, a first gate conductive layer GAT1, a second insulating layer 130, a second gate conductive layer GAT2, a third gate conductive layer GAT3, a fourth insulating layer 150, a source drain conductive layer SD, a via insulating layer 160, a pixel defining layer PDL, the light emitting structure 180, the sealing member CS 140, and the sealing substrate 200.

Each of the elements of the display apparatus is substantially the same as those of the display apparatus of FIG. 1, with the further inclusion of the first and second connecting lines SL1 and SL2, a shielding electrode SE, a sealing member CS, the via insulating layer 160, the pixel defining layer PDL, the light emitting structure 180, and the sealing substrate 200.

The buffer layer 110 may be on the base substrate 100. The active layer ACT may be on the buffer layer 110. The active layer ACT may include a first active pattern ACTa and a second active pattern ACTb. The first insulating layer 120 may be on the buffer layer 110 on which the active layer ACT is located.

The first gate conductive layer GAT1 may be on the first insulating layer 120. The first gate conductive layer GAT1 may include a first-a gate pattern GAT1a and a first-b gate pattern GAT1b spaced apart from the first-a gate pattern GAT1a. The first gate conductive layer GAT1 may further include the first connecting line SL1.

The second insulating layer 130 may be on the first insulating layer 120 on which the first gate conductive layer GAT1 is located.

The second gate conductive layer GAT2 may be on the second insulating layer 130. The second gate conductive layer GAT2 may include a second-a gate pattern GAT2a. The second gate conductive layer GAT2 may further include the second connecting line SL2.

The third insulating layer 140 may be on the second insulating layer 130 on which the second gate conductive layer GAT2 is located.

The third gate conductive layer GAT3 may be on the third insulating layer 140. The third gate conductive layer GAT3 may include a third-a gate pattern GAT3a and a third-b gate pattern GAT3b spaced apart from the third-a gate pattern GAT3a. The third gate conductive layer GAT3 may further include the shielding electrode SE. The shielding electrode SE may include a first shielding electrode SE1 and a second shielding electrode SE2. The first shielding electrode SE1 may overlap with the first connecting line SL1. The second shielding electrode SE2 may overlap with the second connecting line SL2. According to another embodiment, the first and second shielding electrodes SE1 and SE2 may be formed in a single pattern so that the first and second connecting lines SL1 and SL2 may be simultaneously overlapped with the single pattern. The first shielding electrode SE1 and the second shielding electrode SE2 may be floating or a constant voltage may be applied thereto.

The fourth insulating layer 150 may be on the third insulating layer 140 on which the third gate conductive layer GAT3 is located. The source drain conductive layer SD may be on the fourth insulating layer 150. The source drain conductive layer SD may include a first SD pattern SDa, a second SD pattern SDb, and a third SD pattern SDc.

The via insulating layer 160 may be on the source drain conductive layer SD. The via insulating layer 160 may have a single-layer structure, but may have a multi-layered structure including at least two insulating layers. The via insulating layer 160 may be formed using an organic material such as a photoresist, an acrylic resin, a polyimide resin, a polyamide resin, or a siloxane-based resin.

The light emitting structure 180 may include a first electrode 181, a light emitting layer 182 and a second electrode 183.

The first electrode 181 may be on the via insulation layer 160. The first electrode 181 may include a reflective material or a transmissive material in accordance with the emission type of the display apparatus. In example embodiments, the first electrode 181 may have a single layer structure or a multi-layered structure, which may include a metal film, an alloy film, a metal nitride film, a conductive metal oxide film and/or a transparent conductive film.

The pixel defining layer PDL may be on the via insulation layer 160 on which the first electrode 181 is located. The pixel defining layer PDL may be formed using an organic material. For example, the pixel defining layer PDL may include photoresist, acryl-based resin, polyimide-based resin, polyamide-based resin, siloxane-based resin, etc. In some example embodiments, an opening which exposes the first electrode 181 may be formed by etching the pixel defining layer PDL. An emitting area and a non-emitting area of the display apparatus may be defined by the opening of the pixel defining layer PDL. For example, a portion where the opening of the pixel defining layer PDL is located may correspond to an emitting area, and a non-emitting area may correspond to a portion adjacent to the opening of the pixel defining layer PDL.

The light emitting layer 182 may be on the first electrode 181 exposed through the opening of the pixel defining layer PDL. In addition, the light emitting layer 182 may extend on a sidewall of the opening of the pixel defining layer PDL. In some embodiments, the light emitting layer 182 may include an organic light emitting layer (EL), a hole injection layer (HIL), a hole transfer layer (HTL), an electron transfer layer (ETL), an electron injection layer (EIL), etc. In some example embodiments, except for the organic emission layer, the hole injection layer, the hole transport layer, the electron transport layer, and the electron injection layer may be commonly formed to correspond to a plurality of pixels. In some example embodiments, a plurality of organic light emitting layers may be formed using light emitting materials for generating different colors of light such as a red color of light, a green color of light and a blue color of light in accordance with color pixels of the display device. In some example embodiments, the organic light emitting layer of the of the light emitting layer 182 may include a plurality of stacked light emitting materials for generating a red color of light, a green color of light and a blue color of light to thereby emitting a white color of light. Here, elements of the light emitting layer 182 are commonly formed so as to correspond to a plurality of pixels, and each pixel can be divided by a color filter layer.

The second electrode 183 may be on the pixel defining layer PDL and the light emitting layer 182. The second electrode 183 may include a transmissive material or a reflective material in accordance with an emission type of display device. In example embodiments, the second electrode 183 may also have a single layer structure or a multi-layered structure, which may include a metal film, an alloy film, a metal nitride film, a conductive metal oxide film and/or a transparent conductive film.

The sealing member CS may overlap the first and second connecting lines SL1 and SL2 and the first and second shield electrodes SE1 and SE2 on the fourth insulating layer 150. The sealing substrate 200 and the sealing member CS may seal the light emitting structure 180 in the display area DA to prevent or reduce penetration of moisture and oxygen from the outside.

The sealing member CS may be formed on the sealing substrate 200, and bonded with the base substrate 100 by being cured through laser irradiation, or another suitable method, to seal the display region DA in which the light emitting structure 180 is formed. The sealing member CS may be irradiated by a laser beam through the sealing substrate 200. At this time, the shielding electrode SE including molybdenum may prevent or reduce the laser beam from irradiating the first and second connecting lines SL1 and SL2. Accordingly, it is possible to prevent or substantially prevent the damage to the first and second connecting lines SL1 and SL2, which may include aluminum, as a result of the laser irradiation.

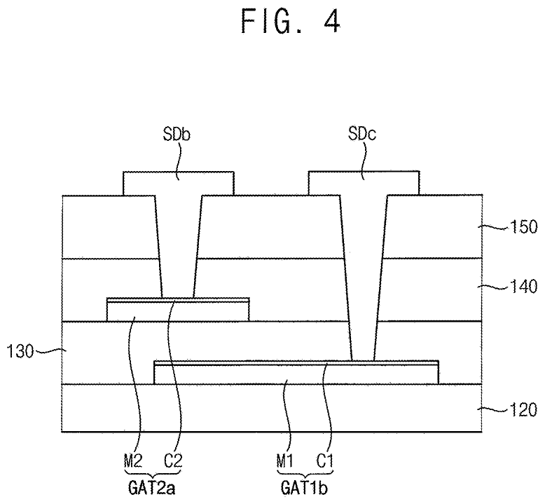

FIG. 4 is a partially enlarged cross-sectional view of a display apparatus according to an example embodiment of the inventive concept.

Referring to FIGS. 1 and 4, the display apparatus may be substantially the same as the display apparatus of FIG. 1, except that the first gate conductive layer GAT1 includes a first main conductive layer M1 and a first capping layer C1, and the second gate conductive layer GAT2 includes a second main conductive layer M2 and a second capping layer C2.

The first-b gate conductive pattern GAT1b may include the first main conductive layer M1 and the first capping layer C1 on the first main conductive layer M1. The first main conductive layer M1 may be formed of a single layer of aluminum or an aluminum alloy. The first capping layer C1 may include titanium (Ti) and may have a thickness of 100 Å (Angstroms) or less.

The second-a gate conductive pattern GAT2a may include the second main conductive layer M2 and the second capping layer C2 on the second main conductive layer M2. The second main conductive layer M2 may be formed of a single layer of aluminum or aluminum alloy. The second capping layer C2 may include titanium and may have a thickness of 100 angstroms or less.

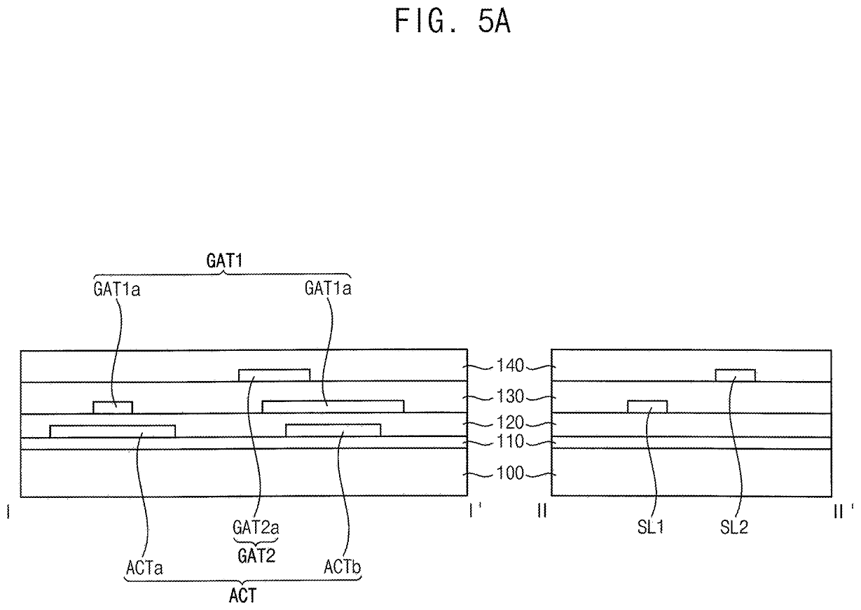

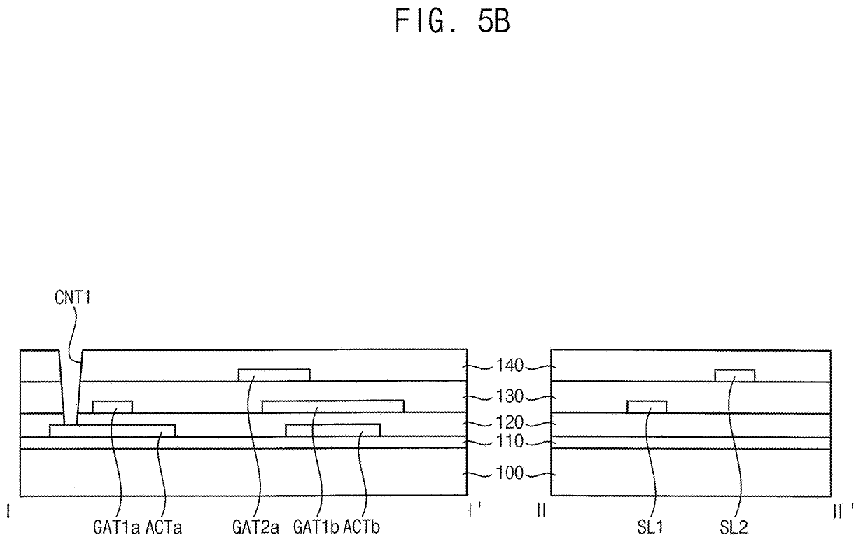

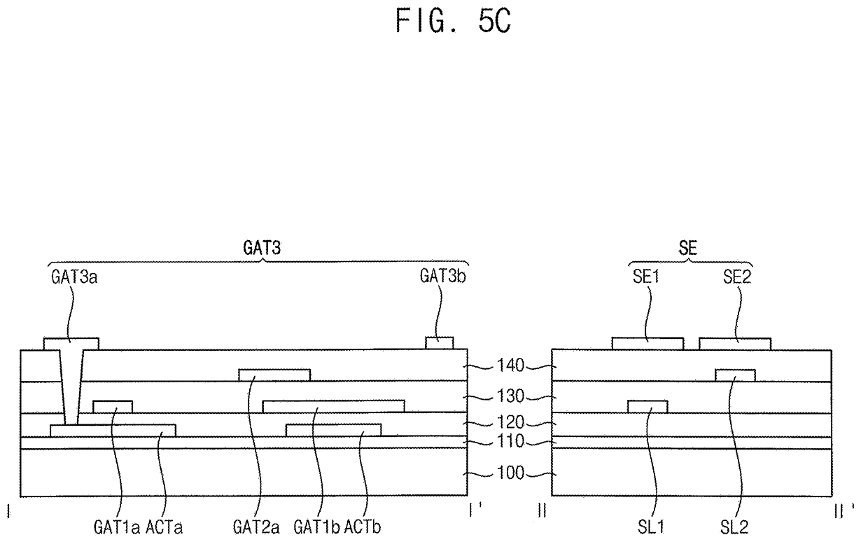

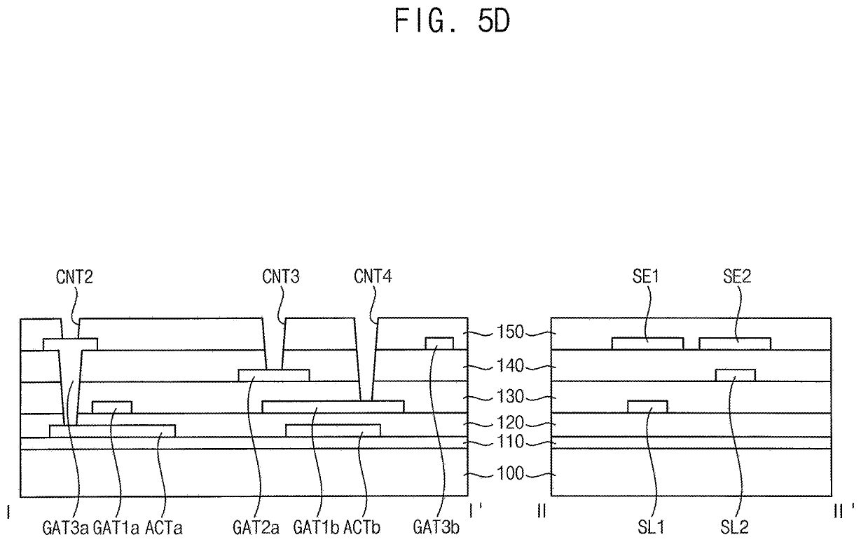

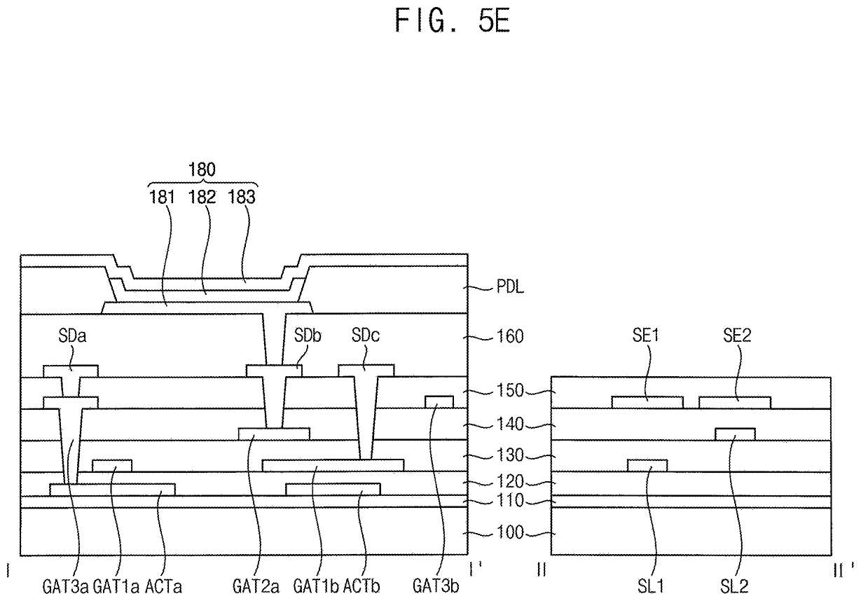

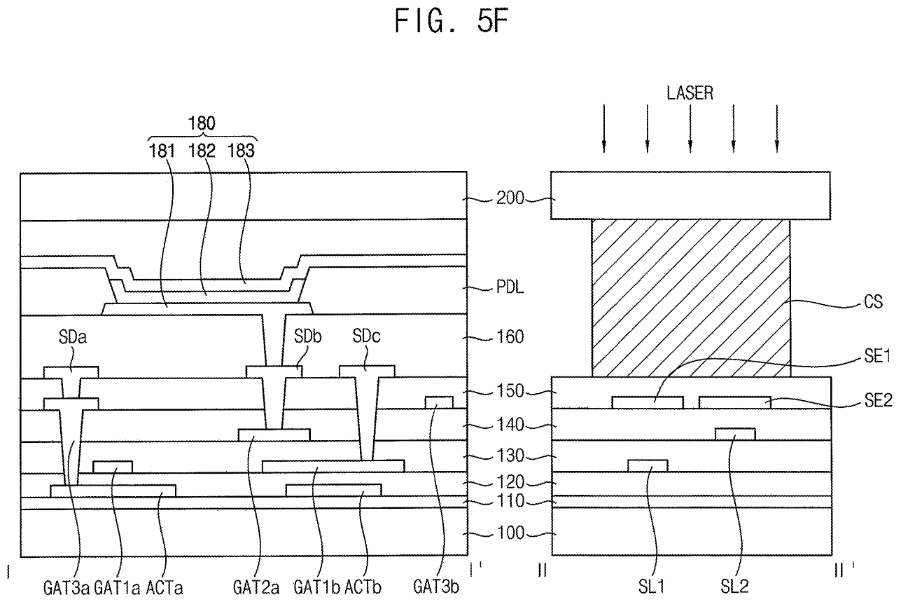

FIGS. 5A-5F are cross-sectional views illustrating a method of manufacturing the display apparatus of FIG. 3.

Referring to FIG. 5A, the buffer layer 110 may be formed on the base substrate 100. The active layer ACT may be formed on the buffer layer 110. The active layer ACT may include the first active pattern ACTa and the second active pattern ACTb. The first insulating layer 120 may be formed on the buffer layer 110 on which the active layer ACT is located.

The first gate conductive layer GAT1 may be formed on the first insulating layer 120. The first gate conductive layer GAT1 may include the first-a gate pattern GAT1a and the first-b gate pattern GAT1b spaced apart from the first-a gate pattern GAT1a. The first gate conductive layer GAT1 may further include the first connecting line SL1.

Thereafter, a portion of the active layer ACT may be doped with an impurity to form a source region and a drain region. Thereafter, the active layer ACT can be activated by heat treatment for dopant activation of the active layer (e.g., rapid thermal annealing (RTA)).

The second gate conductive layer GAT2 may be formed on the second insulating layer 130. The second gate conductive layer may include a second-a gate pattern GAT2a. The second gate conductive layer GAT2 may further include the second connecting line SL2.

The third insulating layer 140 may be formed on the second insulating layer 130 on which the second gate conductive layer GAT2 is located.

Referring to FIG. 5B, a first contact hole CNT1 may be formed through the third insulating layer 140, the second insulating layer 130 and the first insulating layer 120 to expose the first active pattern ACTa.

Here, to improve electrical connection through the first contact hole CNT1, an upper surface of the first active pattern ACTa exposed through the first contact hole CNT1 may be cleaned. For example, a wet cleaning process can be performed using a BOE (Buffered Oxide Etchant) cleaning solution having an etching force against a metal. A cleaning process using the BOE solution may be performed to remove a bottom residue of the first contact hole CNT1 and an oxide film of the exposed first active pattern ACTa.

Because the first gate conductive layer GAT1 and the second gate conductive layer GAT2 are fully covered by the second insulating layer 130 and the third insulating layer 140, respectively, during the formation of the first contact hole CNT 1, there is no fear that the first and second gate conductive layers GAT1, GAT2 will be etched by the cleaning solution. That is, even if the first and second gate conductive layers GAT1, GAT2 are formed of a weak material such as aluminum, during use of the BOE (Buffered Oxide Etchant) cleaning solution, damage can be prevented or substantially prevented.

Referring to FIG. 5C, a third gate conductive layer GAT3 may be formed on the third insulating layer 140 on which the first contact hole CNT 1 is formed. The third gate conductive layer GAT3 may include the third-a gate pattern GAT3a and the third-b gate pattern GAT3b spaced apart from the third-a gate pattern GAT3a. The third gate conductive layer GAT3 may further include the shielding electrode SE. The shielding electrode SE may include the first shielding electrode SE1 and the second shielding electrode SE2.

Referring to FIG. 5D, a fourth insulating layer 150 may be formed on the third insulating layer 140 on which the third gate conductive layer GAT3 is formed. A second contact hole CNT2 passing through the fourth insulating layer 150, a third contact hole CNT3 passing through the fourth insulating layer 150 and the third insulating layer 140, and a fourth contact hole CNT4 through the fourth insulating layer 150, the third insulating layer 140, and the second insulating layer 130 may be formed.

The second to fourth contact holes CNT2, CNT3, and CNT4 expose the third gate conductive layer GAT3, the second gate conductive layer GAT2, and the first gate conductive layer GAT1, respectively, and do not expose the active layer ACT, so that the second through fourth contact holes CNT2, CNT3, and CNT4 can be sufficiently cleaned using a cleaning liquid having no etching force with respect to the metal. For example, it can be washed sufficiently by DI (deionized) water. Therefore, the first and second gate conductive layers GAT1, GAT2 formed of aluminum or the other suitable material(s) may not be damaged.

According to another embodiment, the first and second gate conductive layers GAT1, GAT2 may include capping layers including titanium or other suitable material(s) on main conductive layers formed of aluminum or other suitable material(s). In this case, the capping layer can have a relatively thin thickness sufficient to serve as an etch stopper when forming the second through fourth contact holes CNT2, CNT3 and CNT4.

Referring to FIG. 5E, a source drain conductive layer SD may be formed on the fourth insulating layer 150. The source drain conductive layer SD may include a first SD pattern SDa, a second SD pattern SDb, and a third SD pattern SDc.

The via insulating layer 160 may be formed on the source drain conductive layer SD. A first electrode 181 may be formed on the via insulating layer 160. A pixel defining layer PDL may be formed on the via insulating layer 160 on which the first electrode 181 is located. A light emitting layer 182 may be formed on the first electrode 181 exposed through an opening of the pixel defining layer PDL. The second electrode 183 may be formed on the pixel defining layer PDL and the light emitting layer 182.

Referring to FIG. 5F, a sealing member CS may be formed on the sealing substrate 200. After the sealing member CS is attached to the base substrate 100, a laser beam LASER may be applied to the sealing member CS to cure the sealing member CS. Thus, the display area in which the light emitting structure 180 is formed can be sealed.

At this time, the sealing member CS is irradiated by the laser beam LASER through the sealing substrate 200, so that the shielding electrode SE, which includes molybdenum or another suitable material, is irradiated with the laser beam, preventing or substantially preventing the first and second connecting lines SL1, and SL2 from being irradiated. Accordingly, it is possible to prevent or substantially prevent the first and second connecting lines SL1 and SL2, which may include aluminum or other suitable material, from being damaged by the laser irradiation.

Accordingly, the display apparatus may be manufactured.

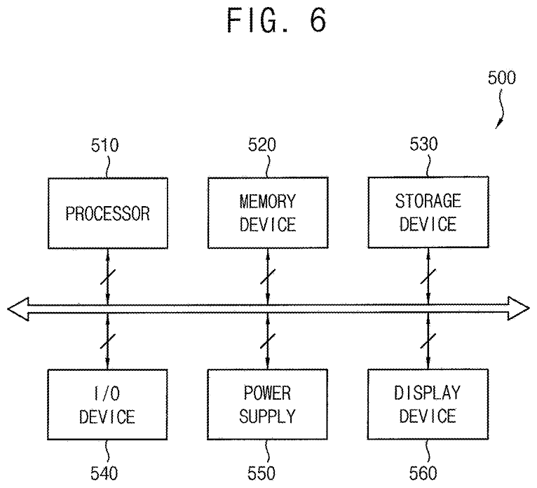

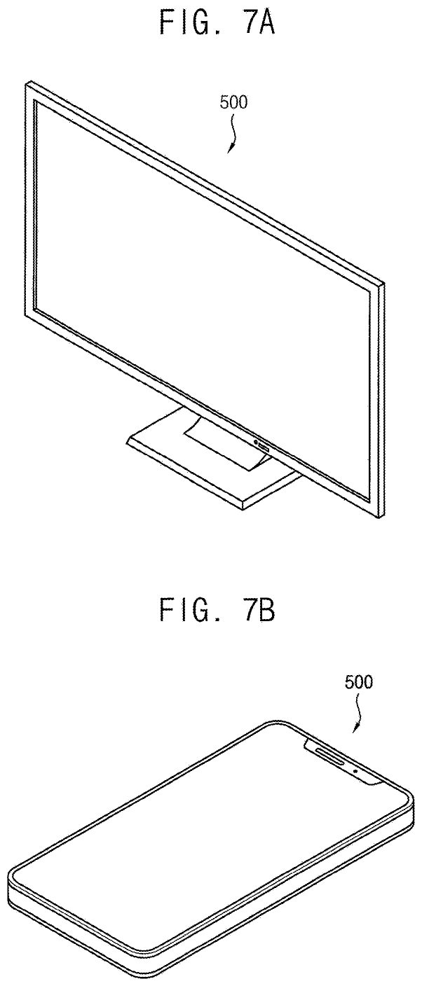

FIG. 6 is a block diagram of an electronic device according to example embodiments. FIG. 7A is a diagram of an example embodiment in which the electronic device of FIG. 6 is implemented as a television. FIG. 7B is a diagram of an example embodiment in which the electronic device of FIG. 6 is implemented as a smart phone.

Referring to FIGS. 6 through 7B, the electronic device 500 may include a processor 510, a memory device 520, a storage device 530, an input/output (I/O) device 540, a power supply 550, and a display device 560. Here, the display device 560 may correspond to the display apparatus of FIG. 1. In addition, the electronic device 500 may further include a plurality of ports for communicating with a video card, a sound card, a memory card, a universal serial bus (USB) device, and/or other electronic components known to a person of ordinary skill in the art. In one embodiment, as illustrated in FIG. 7A, the electronic device 500 may be implemented as a television. In another embodiment, as illustrated in FIG. 7B, the electronic device 500 may be implemented as a smart phone. However, the electronic device 500 is not limited thereto. For example, the electronic device 500 may be implemented as a cellular phone, a video phone, a smart pad, a smart watch, a tablet PC, a car navigation system, a computer monitor, a laptop, a head mounted display (HMD), or other suitable electronic device known to a person of ordinary skill in the art.

The processor 510 may perform various computing functions. The processor 510 may be a microprocessor, a central processing unit (CPU), an application processor (AP), or other suitable processing unit. The processor 510 may be coupled to other components via an address bus, a control bus, a data bus, or other suitable component. Further, the processor 510 may be coupled to an extended bus such as a peripheral component interconnection (PCI) bus. The memory device 520 may store data for operations of the electronic device 500. For example, the memory device 520 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, etc, and/or at least one volatile memory device such as a dynamic random access memory (DRAM) device, a static random access memory (SRAM) device, a mobile DRAM device, etc. The storage device 530 may include a solid state drive (SSD) device, a hard disk drive (HDD) device, a CD-ROM device, or other suitable drive. The I/O device 540 may include an input device such as a keyboard, a keypad, a mouse device, a touchpad, a touch-screen, or other suitable input device and an output device such as a printer, a speaker, or other suitable output device. The power supply 550 may provide power for operations of the electronic device 500.

The display device 560 may be coupled to other components via the buses or other communication links. In some example embodiments, the display device 560 may be included in the I/O device 540. As described above, the display device may reduce wiring resistance to improve display quality, and may prevent or reduce problems during manufacturing.

The present invention can be applied to organic light emitting display devices and various electronic devices including the same. For example, the present invention can be applied to a mobile phone, a smart phone, a video phone, a smart pad, a smart watch, a tablet PC, a car navigation system, a television, a computer monitor, a notebook, and other suitable devices.

The foregoing is illustrative of the inventive concept and is not to be construed as limiting thereof. Although a few example embodiments of the inventive concept have been described, those skilled in the art will readily appreciate that many modifications are possible in the example embodiments without materially departing from the novel teachings and advantages of the inventive concept. Accordingly, all such modifications are intended to be included within the scope of the inventive concept as defined in the claims. In the claims, means-plus-function clauses are intended to cover the structures described herein as performing the recited function and not only structural equivalents but also equivalent structures. Therefore, although illustrative embodiments of the present invention have been described, it is to be understood that the present invention should not be limited to these embodiments but various changes and modifications can be made by one of ordinary skill in the art within the spirit and scope of the present invention as hereinafter claimed by appended claims and equivalents thereof.

What is claimed is:

1. A display apparatus, comprising:
a base substrate;
an active layer on the base substrate and comprising a first active pattern;
a first insulating layer on the active layer;
a first gate conductive layer on the first insulating layer;
a second insulating layer on the first gate conductive layer; and
a third gate conductive layer on the second insulating layer and comprising a third-a gate pattern,
wherein the third gate conductive layer is not directly connected to the first gate conductive layer.

2. The display apparatus of claim 1, wherein the third-a gate pattern is directly connected to the first active pattern through a first contact hole formed through the second insulating layer and the first insulating layer.

3. The display apparatus of claim 2, further comprising:
a fourth insulating layer on the third gate conductive layer; and
a source drain conductive layer on the fourth insulating layer, and including a first SD pattern and a second SD pattern,
wherein the first gate conductive layer includes a first-a gate pattern and a first-b gate pattern, and wherein the first-a gate pattern overlaps the first active pattern, and the first-b gate pattern is spaced apart from the first-a gate pattern,
wherein the first SD pattern is directly connected to the third-a gate pattern through a second contact hole formed through the fourth insulating layer, and
wherein the second SD pattern is directly connected to the first-b gate pattern through a third contact hole formed through the fourth insulating layer and the second insulating layer.

4. The display apparatus of claim 1, further comprising:
a second gate conductive layer on the second insulating layer; and
a third insulating layer on the second gate conductive layer and under the third gate conductive layer,
wherein the third gate conductive layer is not directly connected to the second gate conductive layer.

5. The display apparatus of claim 4, wherein the third-a gate pattern is directly connected to the first active pattern through a first contact hole formed through the third insulating layer, the second insulating layer and the first insulating layer.

6. The display apparatus of claim 1, wherein the active layer comprises polycrystalline silicon.

7. The display apparatus of claim 1, wherein the first gate conductive layer comprises a single layer of aluminum or an aluminum alloy.

8. The display apparatus of claim 7, wherein the first gate conductive layer comprises a main conductive layer and a capping layer on the main conductive layer.

9. The display apparatus of claim 8, wherein the main conductive layer comprises a single layer of aluminum or an aluminum alloy, and the capping layer comprises titanium (Ti) and has a thickness of 100A or less.

10. The display apparatus of claim 1, further comprising:
a sealing member between a display area in which an image is displayed and a peripheral area surrounding the display area; and
a sealing substrate configured to seal elements in the display area with the sealing member, and
wherein the first gate conductive layer further comprises a first connecting line overlapping the sealing member, and
the third gate conductive layer further comprises a shielding electrode between the first connecting line and the sealing member.

11. A display apparatus, comprising:
a base substrate comprising a display area in which an image is displayed and a peripheral area which is a non-display area adjacent to the display area;
an active layer on the base substrate;
a first insulating layer on the active layer;
a first gate conductive layer on the first insulating layer, and comprising a first connecting line;
a second insulating layer on the first gate conductive layer;
a third gate conductive layer on the second insulating layer, and including a first shielding electrode overlapping the first connecting line;
a fourth insulating layer on the third gate conductive layer;
a sealing member on the fourth insulating layer between the display area and the peripheral area, and overlapping the first shielding electrode; and
a sealing substrate configured to seal elements in the display area with the sealing member.

12. A method of manufacturing a display apparatus, comprising:
forming an active layer comprising a first active pattern on a base substrate;
forming a first insulating layer on the active layer;
forming a first gate conductive layer on the first insulating layer;
forming a second insulating layer on the first gate conductive layer;
forming a first contact hole exposing the first active pattern through the second insulating layer and the first insulating layer; and
forming a third gate conductive layer comprising a third-a gate pattern directly connected to the first active pattern via the first contact hole on the second insulating layer, and
wherein, when forming the first contact hole, the first gate conductive layer is fully covered by the second insulating layer.

13. The method of claim 12, wherein after the first contact hole is formed and before the third gate conductive layer is formed, the method further comprises cleaning a surface of the first active pattern which is exposed by the first contact hole with a cleaning solution for etching metal.

14. The method of claim 13, wherein in cleaning the surface of the first active pattern, a wet cleaning process using a buffered oxide etchant is performed.

15. The method of claim 12, wherein after the first gate conductive layer is formed and before the second insulating layer is formed, the method further comprises:
forming a source region and a drain region by doping impurities in a portion of the active layer; and
activating the active layer by heat treating the active layer to activate the dopant.

16. The method of claim 12, wherein the first gate conductive layer comprises a connecting line, and
the third gate conductive layer comprises a shielding electrode overlapping the connecting line.

17. The method of claim 16, further comprising:
forming a sealing member on a sealing substrate;
bonding the sealing substrate and the base substrate on which the third gate conductive layer is formed using the sealing member; and
hardening the sealing member by irradiating the sealing member through the sealing substrate with a laser, and
wherein the shielding electrode is between the sealing member and the connecting line to block the connecting line from being irradiated by the laser.

18. The method of claim 12, wherein before forming the third gate conductive layer, the method further comprises:
forming a second gate conductive layer on the second insulating layer; and
forming a third insulating layer on the second gate conductive layer.

19. The method of claim 12, wherein the first gate conductive layer is formed of a single layer of aluminum or an aluminum alloy.

20. The method of claim 12, wherein the third gate conductive layer comprises molybdenum or molybdenum alloys.
